(19) United States
(12) Patent Application Publication
(10) Pub. No.: US 2026/0334027 A1
(43) Pub. Date: Oct. 22, 2026

(54) DISPLAY DEVICE AND ELECTRONIC DEVICE INCLUDING THE SAME

(71) Applicant: Samsung Display Co., Ltd., Yongin-si (KR)

(72) Inventors: HEEJU WOO, Yongin-si (KR); DAEHYUK IM, Yongin-si (KR)

(21) Appl. No.: 19/578,021

(22) Filed: Mar. 25, 2026

(30) Foreign Application Priority Data
Apr. 21, 2025 (KR) 10-2025-0051859

(51) Int. Cl. H10K 59/131; H10K 59/88

(52) U.S. Cl. CPC H10K 59/131; H10K 59/88

(57) ABSTRACT

In a display device having a display area and a non-display area, the display device includes: a plurality of pad units in the non-display area; at least one dummy pattern unit between adjacent pad units among the plurality of pad units; and an adjacent insulating layer at least between the pad units and the dummy pattern unit, and arranged not to cover at least one area among areas of the plurality of pad units.

### CROSS-REFERENCE TO RELATED APPLICATION

The present application claims priority to and the benefit of Korean Patent Application No. 10-2025-0051859, filed on Apr. 21, 2025, in the Korean Intellectual Property Office, the entire disclosure of which is incorporated herein by reference.

### BACKGROUND

### 1. Field

Aspects of one or more embodiments relate to a display device and an electronic device including the same.

### 2. Description of the Related Art

Recently, uses for display devices have diversified. Display devices are becoming relatively thinner and more lightweight, which has gradually widened the range of uses of display devices. Accordingly, various designs are being attempted to relatively improve the quality of display devices.

These display devices are being applied in various fields. For example, display devices may be applied not only TV sets and monitors for users' visual activities, but also mobile phones, tablet devices, digital watches, indoor and outdoor information displays for transport devices, and other user wearable devices.

Accordingly, consumer demand for display devices with relatively improved electrical reliability in various environments is increasing.

The above information disclosed in this Background section is only for enhancement of understanding of the background and therefore the information discussed in this Background section does not necessarily constitute prior art.

### SUMMARY

Aspects of some embodiments include a display device with relatively improved electrical reliability, and an electronic device including the same.

Aspects of embodiments according to the present disclosure are not limited to the characteristics mentioned above, and other characteristics of embodiments according to the present disclosure that are not mentioned will be understood by the following description and will be more clearly understood by the disclosed embodiments of the disclosure. Further, it will be readily understood that the characteristics of embodiments according to the present disclosure may be realized by the features set forth in the appended claims, and their equivalents, and combinations thereof.

According to one or more embodiments, a display device having a display area and a non-display area includes a plurality of pad units arranged in the non-display area, at least one dummy pattern unit arranged between adjacent pad units among the plurality of pad units, and an adjacent insulating layer arranged at least between the plurality of pad units and the dummy pattern unit, and arranged not to cover at least one area among areas of the plurality of pad units.

According to some embodiments, the display device may further include a circuit member arranged to be electrically connected to the plurality of pad units, and the circuit member may include a plurality of lead units electrically connected to the at least one area, not covered by the adjacent insulating layer, among the areas of the plurality of pad units, and spaced apart from the dummy pattern unit.

According to some embodiments, the dummy pattern unit may be arranged to overlap a space between adjacent lead units among the plurality of lead units.

According to some embodiments, the display device may further include an intermediate insulating layer arranged between the plurality of pad units and the circuit member.

According to some embodiments, each of the plurality of lead units of the circuit member and an area of the corresponding pad unit may be arranged to be in contact with each other.

According to some embodiments, each of the plurality of pad units may include at least one convex portion protruding toward the circuit member, and an area of the at least one convex portion may be arranged to be in contact with the corresponding lead unit.

According to some embodiments, the pad unit may include a base conductive layer, at least one connection conductive layer electrically connected to the base conductive layer, and a convex pattern corresponding to the at least one convex portion and arranged between the base conductive layer and the at least one connection conductive layer.

According to some embodiments, the convex pattern may include an organic material.

According to some embodiments, the dummy pattern unit may include at least one dummy conductive layer, and a dummy insulating layer covering the at least one dummy conductive layer.

According to some embodiments, the dummy pattern unit and the plurality of pad units may have heights based on a thickness direction of the display device, and the height of the dummy pattern unit may not be greater than the height of each of the plurality of pad units.

According to some embodiments, based on a thickness direction of the display device, the adjacent insulating layer and the plurality of pad units may have heights, and the height of the adjacent insulating layer may not be greater than the height of each of the plurality of pad units.

According to one or more embodiments, a display device having a display area and a non-display area includes a plurality of pad units arranged in the non-display area, an adjacent insulating layer arranged between adjacent pad units among the plurality of pad units, and at least one groove arranged in the adjacent insulating layer to be spaced apart from the plurality of pad units.

According to some embodiments, the display device may further include a circuit member arranged to be electrically connected to the plurality of pad units, and the circuit member may include a plurality of lead units electrically connected to the plurality of pad units and spaced apart from the at least one groove.

According to some embodiments, the at least one groove may be arranged to overlap a space between adjacent lead units among the plurality of lead units.

According to some embodiments, the display device may further include an intermediate insulating layer arranged between the plurality of pad units and the circuit member.

According to some embodiments, each of the plurality of lead units of the circuit member and an area of the corresponding pad unit may be arranged to be in contact with each other.

According to some embodiments, each of the plurality of pad units may include at least one convex portion protruding toward the circuit member, and an area of the at least one convex portion may be arranged to be in contact with the lead unit.

According to some embodiments, the pad unit may include a convex pattern including an organic material to correspond to the at least one convex portion.

According to some embodiments, based on a thickness direction of the display device, the adjacent insulating layer and the pad unit may have heights, and the height of the adjacent insulating layer may not be greater than the height of the pad unit.

According to one or more embodiments, an electronic device includes a display device in which a processor executes at least one application and realizes at least one image. According to some embodiments, the display device has a display area and a non-display area, and includes a plurality of pad units arranged in the non-display area, at least one dummy pattern unit arranged between adjacent pad units among the plurality of pad units, and an adjacent insulating layer arranged at least between the pad units and the dummy pattern unit, and arranged not to cover at least one area among areas of the plurality of pad units.

### BRIEF DESCRIPTION OF THE DRAWINGS

The following drawings attached to this specification illustrate aspects of some embodiments of the present disclosure and, together with the detailed description of the disclosure described below, serve to further understand the technical idea of the disclosure; therefore, embodiments according to the present disclosure should not be interpreted as being limited to matters described in such drawings:

FIG. 1 is a schematic plan view of an example of a display device according to some embodiments;

FIG. 2 is a perspective view of the display device of FIG. 1, viewed in one direction;

FIG. 3 is an exploded perspective view of FIG. 2;

FIG. 4 is a schematic block diagram of the structure of the display device shown in FIG. 1;

FIG. 5 is a schematic view of an equivalent circuit of a pixel of the display device shown in FIG. 1;

FIG. 6 is a schematic cross-sectional view of an example of a cross-section taken along the line VI-VI′ of FIGS. 1 to 3;

FIG. 7 is a partial enlarged view of a first connection area CA1 in FIG. 3;

FIG. 8 is a schematic view of an example of a cross-section taken along the line VIII-VIII′ of FIGS. 1 to 3 and 7;

FIG. 9 is a schematic view of an example of a cross-section taken along the line IX-IX′ of FIGS. 1 to 3 and 7;

FIG. 10 is an enlarged view of further details of an area A1 in FIG. 8;

FIGS. 11 to 13 are enlarged views of an area A2 of FIG. 9 according to some embodiments;

FIG. 14 is an exploded perspective view of a portion of a display device according to some embodiments;

FIG. 15 is a partial enlarged view of a first connection area CA1′ in FIG. 14;

FIG. 16 is a schematic view of an example of a cross-section taken along the line XVI-XVI′ of FIGS. 14 and 15;

FIGS. 17 and 18 are enlarged views of aspects of the area A3 in FIG. 16;

FIG. 19 is a view for explaining an electronic device to which a display device according to some embodiments is applied; and

FIG. 20 is a view for explaining various examples of the electronic device of FIG. 19.

### DETAILED DESCRIPTION

As the disclosure allows for various changes and numerous embodiments, certain embodiments will be illustrated in the drawings and described in detail in the written description. Effects and features of the disclosure, and methods of achieving them will be clarified with reference to embodiments described below in detail with reference to the drawings. The disclosure may, however, be embodied in many different forms and should not be construed as being limited to the embodiments set forth herein.

In the following embodiments, the terms “first”, “second”, and the like are not used in a restrictive sense and are used to distinguish one element from another.

The singular forms as used herein are intended to include the plural forms as well unless the context clearly indicates otherwise.

In the following embodiments, it is to be understood that the terms, such as “including” or “having” are intended to indicate the existence of features or components disclosed in the disclosure, and are not intended to preclude the possibility that one or more other features or elements may exist or may be added.

In the following embodiments, it will be understood that, in case that a portion, such as layer, unit, region, or element, is referred to as being “on” another portion, this may include not only a case where the portion is directly on the other portion, but also a case where intervening layers, units, regions, or elements may be present therebetween.

In the following embodiments, terms, such as connect or couple, do not necessarily mean a direct and/or fixed connection or coupling of two members, unless the context clearly indicates otherwise, and do not exclude the case where another member is interposed between the two members.

In the following examples, an x-axis, a y-axis, and a z-axis are not limited to three axes on an orthogonal coordinate system, and may be interpreted in a broad sense that includes such axes. For example, the x-axis, the y-axis, and the z-axis may be orthogonal to one another, but may also represent different directions that are not orthogonal to one another.

Sizes of elements in the drawings may be exaggerated for convenience of explanation. For example, because sizes and/or thicknesses of elements in the drawings are arbitrarily illustrated for convenience of explanation, the disclosure is not limited thereto.

Hereinafter, aspects of some embodiments will be described in more detail with reference to the accompanying drawings. When describing embodiments with reference to the accompanying drawings, the same or corresponding elements are denoted by the same reference numerals, and redundant descriptions thereof are omitted.

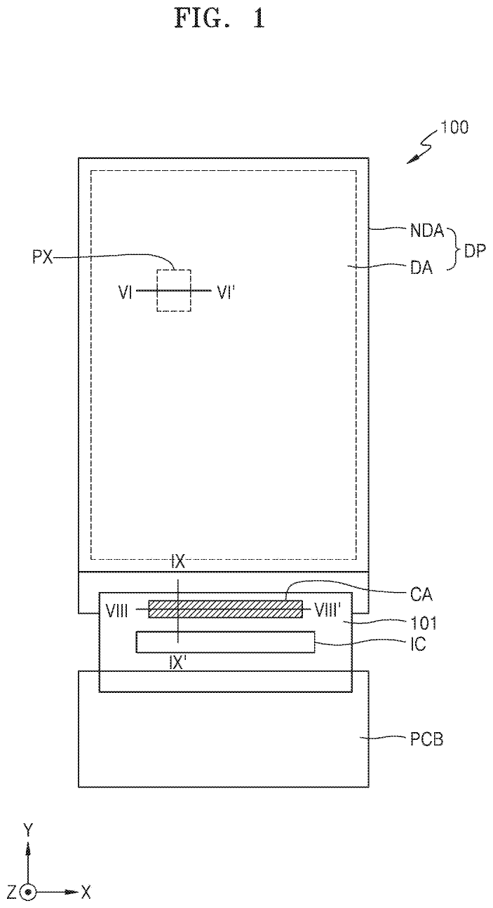

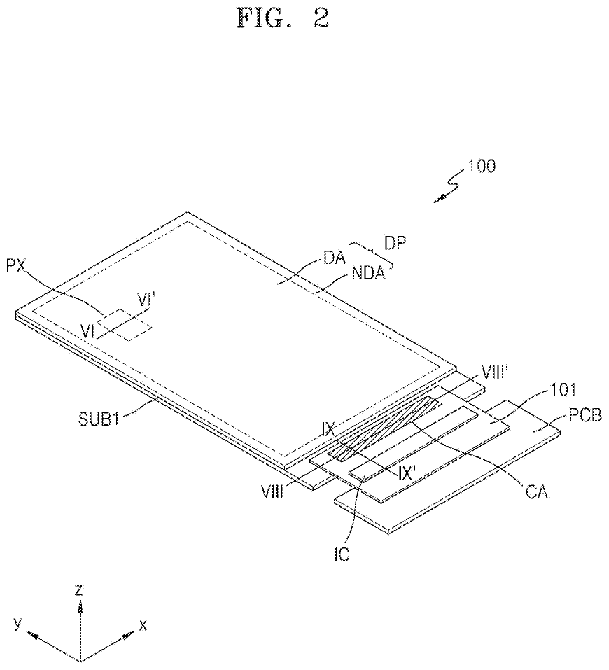

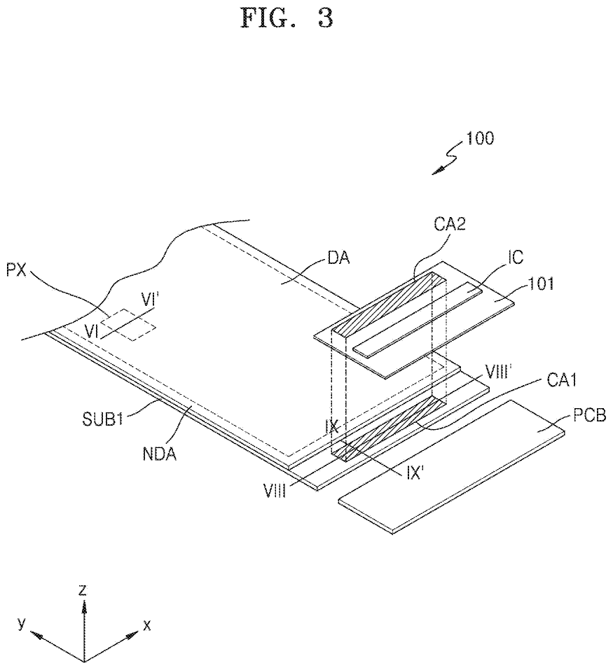

FIG. 1 is a schematic plan view of an example of a display device according to some embodiments. FIG. 2 is a perspective view of the display device of FIG. 1, viewed in one direction. FIG. 3 is an exploded perspective view of FIG. 2.

Referring to FIGS. 1 and 2, a display device 100 may be a device that displays moving images or still images, and may display a screen or perform input and output of data on a display panel DP. The display device 100 may be used as a display screen of various electronic devices, such as televisions, laptops, monitors, billboards, and Internet of things (IoT) devices, as well as portable electronic devices, such as mobile phones, smartphones, tablet personal computers (PCs), mobile communication terminals, electronic organizers, e-books, portable multimedia players (PMPs), navigation systems, and ultra mobile PCs (UMPCs).

The display device 100 according to some embodiments may also be applied to electronic devices, such as wearable devices, for example, smart watches, watch phones, glasses-type displays, and head mounted displays (HMDs). The display device 100 according to some embodiments may also be used as a display of various electronic devices, for example, dashboards of automobiles, center information displays (CIDs) on the center fascia or dashboards of automobiles, room mirror displays replacing side mirrors of automobiles, and displays on the rear surfaces of front seats to serve as entertainment devices for backseat passengers of automobiles.

According to some embodiments, the display device 100 may include a display panel DP, a circuit member 101, and a printed circuit board PCB.

The display panel DP may include a substrate SUB1. On the substrate SUB1, a display area DA which emits visible light and a non-display area NDA located on one side or outside (e.g., in a periphery or outside a footprint) of the display area DA may be arranged.

Of these areas, the display area DA may include at least one pixel PX arranged on the substrate SUB1.

The non-display area NDA may be an area where a plurality of pixels are not arranged and may surround (e.g., in a periphery or outside a footprint of) the display area DA. According to some embodiments, the non-display area NDA may be positioned outside (e.g., in a periphery or outside a footprint of) an edge of the display area DA or outside a plurality of edges of the display area DA.

The non-display area NDA may include a first connection area CA1.

The circuit member 101 and the like may be arranged to be connected, for example, electrically connected to or in contact with a portion of the non-display area NDA. For example, as shown in FIG. 3, a second connection area CA2 arranged on the circuit member 101 and the first connection area CA1 in the non-display area NDA arranged on the substrate SUB1 may be arranged to be connected to or in contact with each other along a third direction (e.g., a Z-axis direction of FIGS. 1 to 3). Here, a first direction (e.g., an X-axis direction of FIGS. 1 to 3) may be a width or length direction of the substrate SUB1, a second direction (e.g., a Y-axis direction of FIGS. 1 to 3) may be a direction crossing (or orthogonal to) the first direction, and the third direction may be a direction crossing (or orthogonal to) the first direction and the second direction, for example, may correspond to a thickness direction of the substrate SUB1.

The circuit member 101 may include at least one circuit element, and may include, for example, a driver chip IC. The circuit member 101 may have various forms, and may include, for example, a material with flexibility, and, according to some embodiments, may include a flexible printed circuit board (FPC) form.

The circuit member 101 may be electrically connected to the display panel DP and, for example, may transmit an electrical signal to the display panel DP. According to some embodiments, the driver chip IC of the circuit member 101 may transmit an electrical signal to the display panel DP.

According to some embodiments, the circuit member 101 may be electrically connected to the printed circuit board PCB. In this case, the printed circuit board PCB may transmit an electrical signal to the circuit member 101. The printed circuit board PCB may include a flexible printed circuit board (FPC).

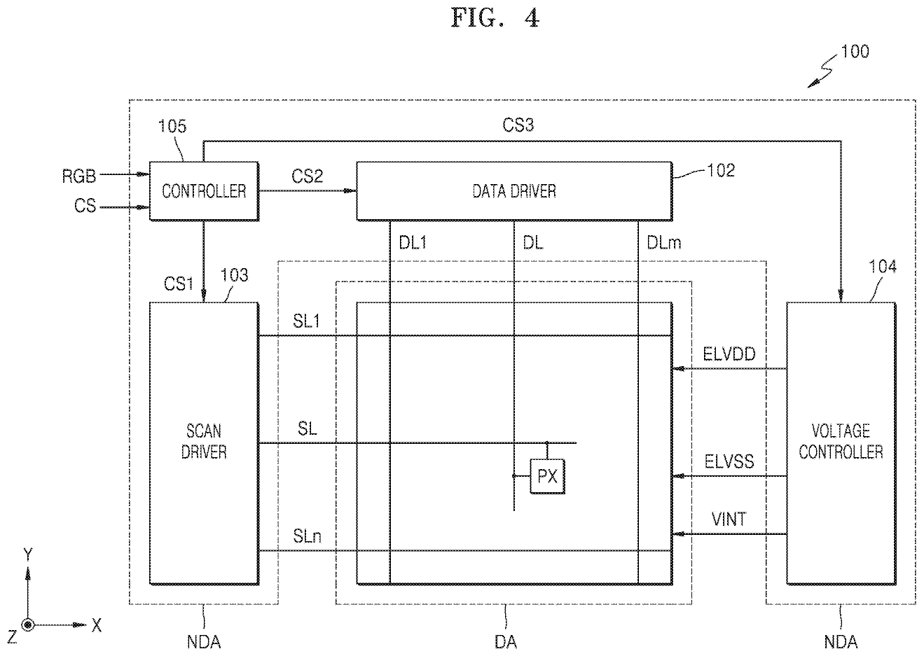

FIG. 4 is a schematic block diagram of the structure of the display device shown in FIG. 1.

Referring to FIG. 4, at least one scan line SL and at least one data line DL may be arranged in the display area DA. For example, a plurality of scan lines SL1, . . . , SLn extending along the first direction (the x-axis direction), a plurality of data lines DL1, . . . , DLm extending along a direction crossing the first direction, for example, the second direction (the y-axis direction), and a plurality of pixels PX may be located in the display area DA. Here, m and n denote natural numbers. Although FIG. 4 illustrates a single pixel PX for convenience of illustration, as a person having ordinary skill in the art would appreciate, the display device 100 may include any suitable number of pixels PX according to the design and size of the display device 100.

Wirings, along which electrical signals may be applied to the plurality of pixels PX, may include the plurality of scan lines SL1, . . . , SLn, and the plurality of data lines DL1, . . . , DLm. The plurality of scan lines SL1, . . . , SLn, for example, may be arranged in a plurality of rows extending in the first direction (the x-axis direction) to transmit scan signals to the pixels PX. The plurality of data lines DL1, . . . , DLm, for example, may be arranged in a plurality of columns extending in the second direction (the y-axis direction) to transmit data signals to the pixels PX. The plurality of pixels PX may be positioned at portions where the plurality of scan lines SL1, . . . , SLn and the plurality of data lines DL1, . . . , DLm cross each other.

Each pixel PX may include an emission element to generate at least one type of light, for example, red light, green light, blue light, or white light. For example, each pixel PX may include an organic light-emitting diode OLED as an emission element, but is not limited thereto.

In the non-display area NDA may be arranged a data driver 102 for applying data signals to the display area DA, a scan driver 103 for applying scan signals to the display area DA, a voltage controller 104 for controlling voltages applied to the display area DA, and a controller 105 which may control the data driver 102, the scan driver 103, and the voltage controller 104.

The voltage controller 104 may generate and control a first voltage ELVDD, a second voltage ELVSS, and an initialization voltage VINT which are applied to the display area DA.

The first voltage ELVDD, the second voltage ELVSS, and the initialization voltage VINT may be applied to the plurality of pixels PX. For example, the first voltage ELVDD may be a positive voltage, and the second voltage ELVSS may be a negative voltage or a ground voltage. That is, the second voltage ELVSS may have a lower level than the first voltage ELVDD.

The controller 105 may receive image signals RGB and a control signal CS from another member (e.g., a system board). The controller 105 may generate image data DATA by converting a data format of the image signals RGB to be appropriate to an interface between the data driver 102 and the controller 105. The controller 105 may apply the image data DATA having the converted data format to the data driver 102.

The controller 105 may generate and output a first control signal CS1, a second control signal CS2, and a third control signal CS3, in response to the control signal CS. The first control signal CS1 may be defined as a scan control signal and the second control signal CS2 may be defined as a data control signal. The first control signal CS1 may be applied to the scan driver 103. The second control signal CS2 may be applied to the data driver 102, and the third control signal CS3 may be applied to the voltage controller 104.

The scan driver 103 may generate a plurality of scan signals, in response to the first control signal CS1. The plurality of scan signals may be applied to the plurality of pixels PX through the plurality of scan lines SL1, . . . , SLn.

The data driver 102 may generate a plurality of data voltages corresponding to the image data DATA, in response to the second control signal CS2. The plurality of data voltages may be applied to the plurality of pixels PX through the plurality of data lines DL1, . . . , DLm. The data driver 102 may simultaneously apply the data voltages, which are generated in units of pixel rows, to the plurality of pixels PX through the plurality of data lines DL1, . . . , DLm.

The plurality of pixels PX may receive the plurality of data voltages, in response to the plurality of scan signals. The plurality of pixels PX may display an image by emitting light of brightness corresponding to the plurality of data voltages. The plurality of pixels PX may display the image by emitting light sequentially or simultaneously.

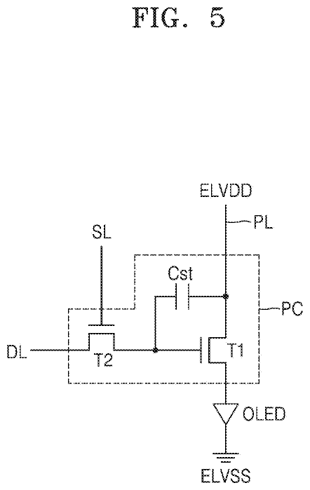

FIG. 5 is a schematic view of an equivalent circuit of a pixel of the display device shown in FIG. 1. Although FIG. 5 illustrates various components in a circuit of a pixel according to some embodiments, embodiments according to the present disclosure are not limited thereto, and according to various embodiments, the circuit may include additional components without departing from the spirit and scope of embodiments according to the present disclosure.

Referring to FIG. 5, a pixel circuit PC may be connected to a display element, for example, an organic light-emitting diode OLED. The pixel circuit PC may be located in the display area DA. The pixel circuit PC may at least include a driving thin-film transistor T1, a switching thin-film transistor T2, and a storage capacitor Cst. The organic light-emitting diode OLED may emit at least one light, for example, red light, green light, or blue light or red light, green light, blue light, or white light.

The switching thin-film transistor T2 may be connected to a scan line SL and a data line DL, and may transmit a data signal or data voltage, which is input from the data line DL, to the driving thin-film transistor T1 based on a scan signal or switching voltage input from the scan line SL. The storage capacitor Cst may be connected to the switching thin-film transistor T2 and a driving voltage line PL, and may store a voltage corresponding to a difference between a voltage transmitted from the switching thin-film transistor T2 and a first voltage ELVDD applied to the driving voltage line PL.

The driving thin-film transistor T1 may be connected to the driving voltage line PL and the storage capacitor Cst, and may control a driving current, which flows in the organic light-emitting diode OLED from the driving voltage line PL, in response to a voltage value stored in the storage capacitor Cst. The organic light-emitting diode OLED may emit light with a certain brightness according to the driving current. A counter electrode of the organic light-emitting diode OLED may receive a second voltage ELVSS.

Although FIG. 5 shows that the pixel circuit PC includes two thin-film transistors and one storage capacitor, the pixel circuit PC may include at least three, four, or five thin-film transistors, and may include at least two or three capacitors.

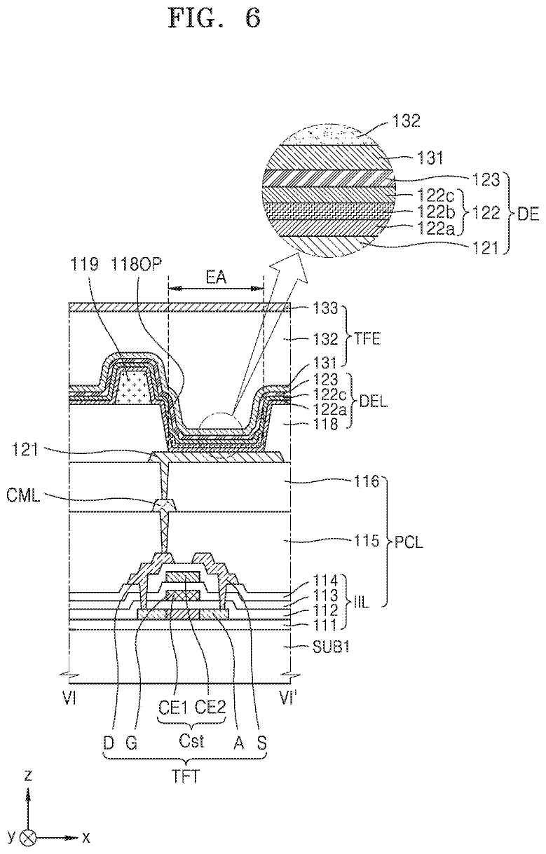

FIG. 6 is a schematic cross-sectional view of an example of a cross-section taken along the line VI-VI′ of FIGS. 1 to 3.

Referring to FIGS. 1 to 3 and 6, the display device 100 may include the display panel DP. The display panel DP may include a substrate SUB1, a buffer layer 111, a pixel circuit layer PCL, a display element layer DEL, and an encapsulation unit TFE.

The substrate SUB1 may include a glass material, for example, a transparent glass material mainly including SiO2. However, it is not limited thereto, and the substrate SUB1 may include a plastic material. The plastic material may include polyethersulfone (PES), polyacrylate (PAR), polyetherimide (PEI), polyethylene naphthalate (PEN), polyethylene terephthalate (PET), polyphenylene sulfide (PPS), polyarylate, polyimide, polycarbonate (PC), cellulose triacetate (TAC), cellulose acetate propionate (CAP), or the like. According to some embodiments, the substrate SUB1 may have a multi-layer structure which includes the plastic material, and may further include at least one barrier layer.

According to some embodiments, the substrate SUB1 may have flexible, rollable, and bendable characteristics.

According to some embodiments, the buffer layer 111 may be arranged on the substrate SUB1. The buffer layer 111 may include an inorganic insulating material, such as silicon nitride, silicon oxynitride, and silicon oxide, and may be a single layer or multi-layer including the inorganic insulating material.

The pixel circuit layer PCL may be arranged on the buffer layer 111. The pixel circuit layer PCL may include an inorganic insulating layer IIL, a first planarization layer 115, and a second planarization layer 116 which are arranged below or/and above a thin-film transistor TFT included in the pixel circuit PC and components of the thin-film transistor TFT. The inorganic insulating layer IIL may include a first gate insulating layer 112, a second gate insulating layer 113, and an interlayer insulating layer 114.

The thin-film transistor TFT may include a semiconductor layer A, and the semiconductor layer A may include polysilicon. According to some embodiments, the semiconductor layer A may include amorphous silicon, an oxide semiconductor, or an organic semiconductor. The semiconductor layer A may include a channel region, and a drain region and a source region arranged on opposite sides of the channel region, respectively. A gate electrode G may overlap the channel region.

The gate electrode G may include a conductive material, for example, may include a low-resistance metal material. According to some embodiments, the gate electrode G may include a conductive material including molybdenum (Mo), aluminum (Al), copper (Cu), titanium (Ti), or the like, and may be formed as a multi-layer or single layer including the material.

The first gate insulating layer 112 between the semiconductor layer A and the gate electrode G may include an insulating material, for example, may include an inorganic insulating material, such as silicon oxide (SiO2), silicon nitride (SiNX), silicon oxynitride (SiON), aluminum oxide (Al2O3), titanium oxide (TiO2), tantalum oxide (Ta2O5), hafnium oxide (HfO2), or zinc oxide (ZnOX), and the zinc oxide (ZnOX) may be zinc oxide (ZnO) and/or zinc peroxide (ZnO2).

The second gate insulating layer 113 may cover the gate electrode G. The second gate insulating layer 113 may include an insulating material, for example, similar to the first gate insulating layer 112, may include an inorganic insulating material, such as silicon oxide (SiO2), silicon nitride (SiNX), silicon oxynitride (SiON), aluminum oxide (Al2O3), titanium oxide (TiO2), tantalum oxide (Ta2O5), hafnium oxide (HfO2), or zinc oxide (ZnOX), and the zinc oxide (ZnOX) may be zinc oxide (ZnO) and/or zinc peroxide (ZnO2).

According to some embodiments, an upper electrode CE2 of the storage capacitor Cst may be arranged on the second gate insulating layer 113. The upper electrode CE2 may overlap the gate electrode G which is located below the upper electrode CE2.

The gate electrode G and the upper electrode CE2, which overlap each other with the second gate insulating layer 113 arranged between the gate electrode G and the upper electrode CE2, may also form the storage capacitor Cst of the pixel circuit PC. For example, the gate electrode G may function as a lower electrode CE1 of the storage capacitor Cst.

In FIG. 6, the storage capacitor Cst and the thin-film transistor TFT overlap each other, but according to some embodiments, the storage capacitor Cst may be formed not to overlap the thin-film transistor TFT.

The upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or a multi-layer of the material.

The interlayer insulating layer 114 may cover the upper electrode CE2. The interlayer insulating layer 114 may include an insulating material, for example, may include silicon oxide (SiO2), silicon nitride (SiNX), silicon oxynitride (SiON), aluminum oxide (Al2O3), titanium oxide (TiO2), tantalum oxide (Ta2O5), hafnium oxide (HfO2), or zinc oxide (ZnOx). The zinc oxide (ZnOX) may be zinc oxide (ZnO) and/or zinc peroxide (ZnO2). The interlayer insulating layer 114 may be a single layer or multi-layer including the inorganic insulating material.

A drain electrode D and a source electrode S may each be located on the interlayer insulating layer 114. The drain electrode D and the source electrode S may include a conductive material, for example, may include a metal material, as a specific example, may include molybdenum (Mo), aluminum (Al), copper (Cu), titanium (Ti), or the like, and may be formed as a multi-layer or single layer including the material. According to some embodiments, the drain electrode D and the source electrode S may have a multi-layer structure of Ti/Al/Ti.

The first planarization layer 115 may be arranged to cover the drain electrode D and the source electrode S. The first planarization layer 115 may include various insulating materials, for example, may include an organic insulating layer, and according to some embodiments, may include a general-purpose polymer, such as polymethylmethacrylate (PMMA) or polystyrene (PS), a polymer derivative having a phenol group, an acrylic polymer, an imide polymer, an aryl ether polymer, an amide-based polymer, a fluorinated polymer, a p-xylene polymer, a vinyl alcohol polymer, and a blend thereof.

According to some embodiments, a connection electrode CML may be arranged on the first planarization layer 115. The connection electrode CML may be connected to the drain electrode D or the source electrode S through a contact hole of the first planarization layer 115. The connection electrode CML may include a material with good conductivity. The connection electrode CML may include a conductive material including molybdenum (Mo), aluminum (Al), copper (Cu), titanium (Ti), or the like, and may be formed as a multi-layer or single layer including the material. According to some embodiments, the connection electrode CML may have a multi-layer structure of Ti/Al/Ti.

The second planarization layer 116 may be arranged to cover the connection electrode CML. The second planarization layer 116 may include various insulating materials, for example, an organic insulating layer, and according to some embodiments, a general-purpose polymer, such as polymethylmethacrylate (PMMA) or polystyrene (PS), a polymer derivative having a phenol group, an acrylic polymer, an imide polymer, an aryl ether polymer, an amide-based polymer, a fluorinated polymer, a p-xylene polymer, a vinyl alcohol polymer, and a blend thereof.

The display element layer DEL may be arranged on the pixel circuit layer PCL. According to some embodiments, a structure may be applied in which at least one of the display element layers DEL is arranged in the same layer as one layer of the pixel circuit layer PCL or arranged below the pixel circuit layer PCL.

The display element layer DEL may include a display element DE. The display element DE may be an organic light-emitting diode OLED. A pixel electrode 121 of the display element DE may be electrically connected to the connection electrode CML through a contact hole of the second planarization layer 116.

The pixel electrode 121 may include a conductive material, for example, may include a conductive oxide, such as indium tin oxide (ITO), indium zinc oxide (IZO), zinc oxide (ZnO), indium oxide (In2O3), indium gallium oxide (IGO), or aluminum zinc oxide (AZO). According to some embodiments, the pixel electrode 121 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. According to some embodiments, the pixel electrode 121 may further include a film that includes ITO, IZO, ZnO, or In2O3 and is located above/below the reflective film.

A pixel defining layer 118 including an opening 118OP, which corresponds to at least one area (e.g., an area including a center) of the pixel electrode 121, may be arranged on the pixel electrode 121. The pixel defining layer 118 may include an organic insulating material and/or an inorganic insulating material. The opening 118OP may define an emission area EA of light emitted from the display element DE (hereinafter, referred to as an emission area of the display element DE). For example, at least a part of a width of the opening 118OP may correspond to a width of the emission area EA of the display element DE.

According to some embodiments, the pixel defining layer 118 may include a black-based light-shielding material, and the light-shielding material may include resin or paste including carbon black, carbon nanotubes, or black dye, metal particles, for example, nickel, aluminum, molybdenum, and alloys thereof, metal oxide particles (e.g., chromium oxide), or metal nitride particles (e.g., chromium nitride). In case that the pixel defining layer 118 includes a light-shielding material, external light reflections due to metal structures arranged below the pixel defining layer 118 may be relatively reduced.

According to some embodiments, a spacer 119 may be arranged on the pixel defining layer 118. The spacer 119 may be arranged to suppress damage to the substrate SUB1 in a method of manufacturing the display device. A mask sheet may be used in case of manufacturing the display panel DP. The mask sheet may enter the opening 118OP of the pixel defining layer 118 or may be in close contact with the pixel defining layer 118, thereby causing a defect that a portion of the substrate SUB1 is damaged or broken upon depositing a deposition material on the substrate SUB1. The spacer 119 may suppress such damage or breakdown of the substrate SUB1 due to the mask sheet.

The spacer 119 may include an insulating material, for example, an organic insulating material, such as polyimide. According to some embodiments, the spacer 119 may include an inorganic insulating material, such as silicon nitride or silicon oxide, or may include an organic insulating material and an inorganic insulating material.

According to some embodiments, the spacer 119 may include a different material from the pixel defining layer 118. According to some embodiments, the spacer 119 may include the same material as the pixel defining layer 118. In this case, the pixel defining layer 118 and the spacer 119 may be formed together during a mask process using a halftone mask or the like.

An intermediate layer 122 may be arranged on the pixel defining layer 118. The intermediate layer 122 may include an emission layer 122b arranged in the opening 118OP of the pixel defining layer 118. The emission layer 122b may include a high-molecular or low-molecular organic material that emits light of a certain color.

A first functional layer 122a and a second functional layer 122c may be arranged above and below the emission layer 122b, respectively. The first functional layer 122a, for example, may include a hole transport layer (HTL) or may include the hole transport layer and a hole injection layer (HIL). The second functional layer 122c may be a component arranged on the emission layer 122b, and may include an electron transport layer (ETL) and/or an electron injection layer (EIL). The first functional layer 122a and/or the second functional layer 122c may be common layers formed to cover the entire substrate SUB1, similar to a counter electrode 123 to be described later.

The counter electrode 123 may include a conductive material having a relatively low work function. For example, the counter electrode 123 may include a (semi)transparent layer that includes silver (Ag), magnesium (Mg), aluminum AL, platinum (Pt), palladium PD, gold (Au), nickel (Ni), neodymium (Nd), iridium (Ir), chromium (Cr), lithium (Li), calcium (Ca), or an alloy thereof. According to some embodiments, the counter electrode 123 may further include a layer, such as ITO, IZO, ZnO, or In2O3, arranged on the (semi)transparent layer including the aforementioned material.

In some embodiments, a capping layer may be further arranged on the counter electrode 123. The capping layer may include LiF, an inorganic material, or/and an organic material.

The encapsulation unit TFE may be arranged on the counter electrode 123. According to some embodiments, the encapsulation unit TFE may include at least one inorganic encapsulation layer and at least one organic encapsulation layer. For example, the encapsulation unit TFE may include a first inorganic encapsulation layer 131, an organic encapsulation layer 132, and a second inorganic encapsulation layer 133 that are sequentially stacked.

The first inorganic encapsulation layer 131 and the second inorganic encapsulation layer 133 may include at least one inorganic material, selected from aluminum oxide, titanium oxide, tantalum oxide, hafnium oxide, zinc oxide, silicon oxide, silicon nitride, or silicon oxynitride. The organic encapsulation layer 132 may include a polymer-based material. The polymer-based material may include acrylic resin, epoxy resin, polyimide, and polyethylene. According to some embodiments, the organic encapsulation layer 132 may include acrylate.

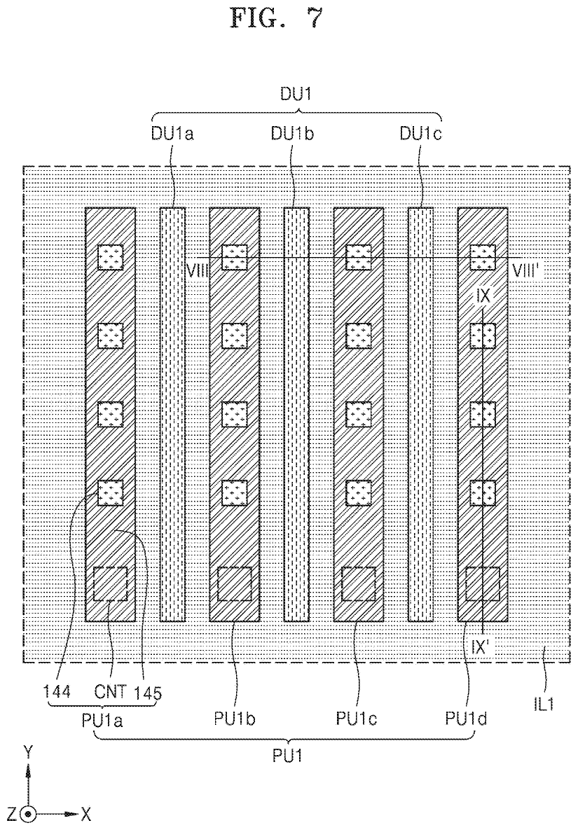

FIG. 7 is a partial enlarged view of a first connection area CA1 in FIG. 3;

Referring to FIG. 7, a first connection area CA1 may include a plurality of pad units PU1. For example, FIG. 7 shows a plurality of pad units PU1 including a first pad unit PU1a, a second pad unit PU1b, a third pad unit PU1c, and a fourth pad unit PU1d. According to some embodiments, the number of the plurality of pad units PU1 may be determined in various ways depending on the conditions of the display panel DP. According to some embodiments, the number of the plurality of pad units PU1 arranged on the first connection area CA1 may be 1, 2, 3, 4, 5, or more.

Each of the plurality of pad units PU1 may have a width and a length. For example, each pad unit PU1 may have a length by extending in the second direction (the Y-axis direction) and a width with respect to the first direction (the X-axis direction).

The plurality of pad units PU1 may be arranged spaced apart from one another along the first direction (the X-axis direction). According to some embodiments, the plurality of pad units PU1 may be arranged in parallel to be spaced apart from one another along the first direction (the X-axis direction).

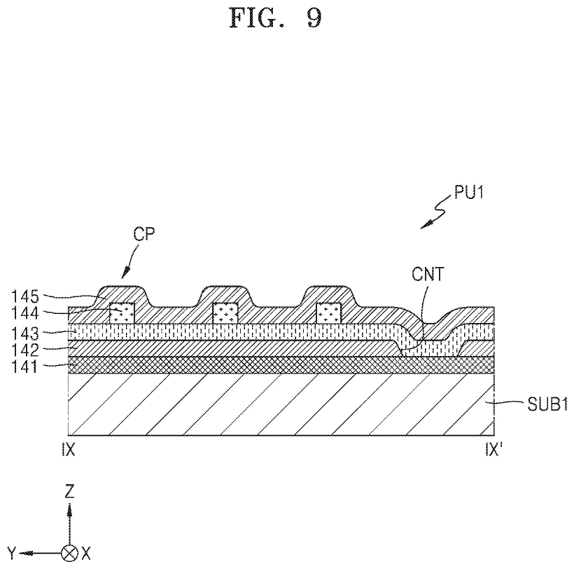

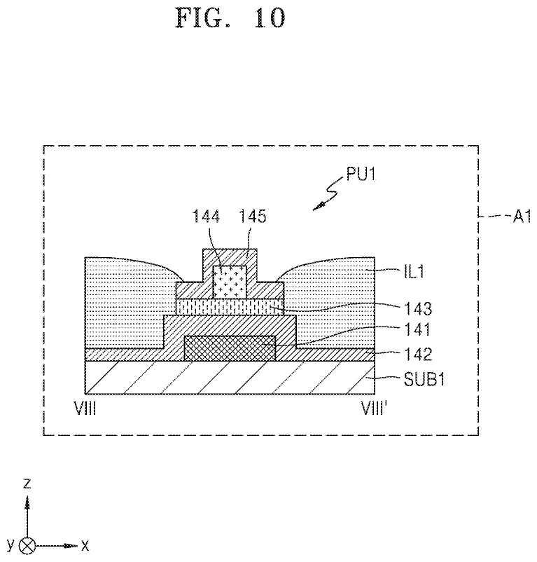

At least one convex pattern 144 and a conductive layer covering the convex pattern 144 may be arranged on each of the plurality of pad units PU1, and an opening may be arranged in an area of the corresponding pad unit PU1. According to some embodiments, the pad unit PU1 may include at least one convex pattern 144, a second connection conductive layer 145 covering the at least one convex pattern 144, and a contact hole CNT arranged in an area of the pad unit PU1. As will be described later in FIGS. 9 and 10, the convex pattern 144 shown in FIG. 7 is covered by the second connection conductive layer 145, but for convenience of explanation, the convex pattern 144 of FIG. 7 is illustrated with a solid line.

At least one dummy pattern unit DU1 may be arranged between two adjacent pad units PU1. For example, as shown in FIG. 7, one dummy pattern unit DU1a may be arranged between the first pad unit PU1a and the second pad unit PU1b. The dummy pattern unit DU1 may be arranged spaced apart from the two adjacent pad units PU1 along the first direction (the X-axis direction).

According to some embodiments, a gap between a pad unit PU1 adjacent to the dummy pattern unit DU1 on one side and the dummy pattern unit DU1 may be equal to a gap between a pad unit PU1 adjacent to the dummy pattern unit DU1 on another side and the dummy pattern unit DU1. For example, based on the dummy pattern unit DU1 arranged between the first pad unit PU1a and the second pad unit PU1b, a gap between the dummy pattern unit DU1 and the first pad unit PU1a may be substantially the same as a gap between the dummy pattern unit DU1 and the second pad unit PU1b.

According to some embodiments, the dummy pattern unit DU1 may be arranged parallel to two adjacent pad units PU1 along the first direction.

According to some embodiments, each of the plurality of pad units PU1 and each of the plurality of dummy pattern units DU1 may be alternately arranged to be spaced apart from each other along the first direction (the X-axis direction).

An adjacent insulating layer IL1 may be arranged in a space between the adjacent pad unit PU1 and the dummy pattern unit DU1 and a space between two adjacent pad units PU1. According to some embodiments, the adjacent insulating layer IL1 may also be arranged around the pad unit PU1 and the dummy pattern unit DU1, for example, may be arranged to surround the pad unit PU1 and the dummy pattern unit DU1. According to some embodiments, the adjacent insulating layer IL1 may be arranged to be in contact with the pad unit PU1 and the dummy pattern unit DU1 on the first connection area CA1. According to some embodiments, the adjacent insulating layer IL1 may be arranged to cover the entire first connection area CA1 excluding the pad unit PU1 and the dummy pattern unit DU1.

The adjacent insulating layer IL1 may include an insulating material, for example, an insulating material including an organic material.

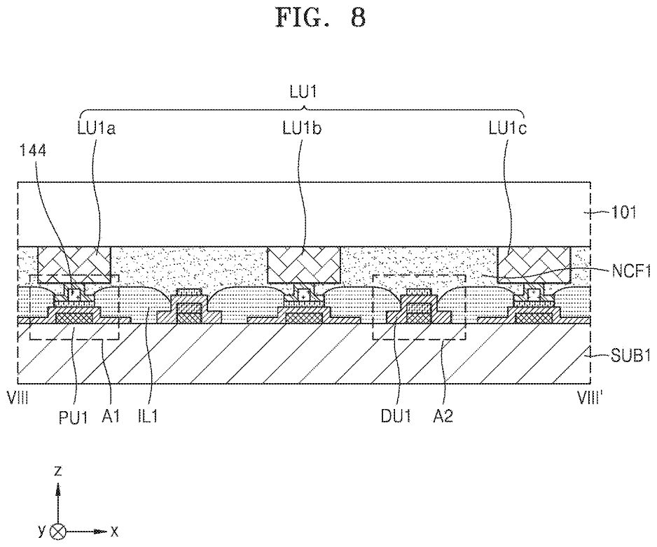

FIG. 8 is a schematic view of an example of a cross-section taken along the line VIII-VIII′ of FIGS. 1 to 3 and 7.

Referring to FIG. 8, the first connection area CA1 on the substrate SUB1 and the second connection area CA2 on the circuit member 101 may be connected to, for example, in contact with each other along the third direction (the Z-axis direction). Accordingly, the display panel DP and the circuit member 101 may be electrically connected.

The pad unit PU1 and the dummy pattern unit DU1 may be arranged on the substrate SUB1, and an area of the pad unit PU1 may be electrically connected to the circuit member 101, for example, may be in contact with the circuit member 101. The pad unit PU1 and the circuit member 101 may be electrically connected.

A lead unit LU1 protruding in a direction toward the pad unit PU1 may be arranged on the circuit member 101. The lead unit LU1 may extend along the second direction (the Y-axis direction). The lead unit LU1 according to some embodiments may be arranged as a plurality of lead units, and the plurality of lead units LU1 may be arranged spaced apart along the first direction (the X-axis direction). For example, the plurality of lead units LU1 may be arranged in parallel along the first direction (the X-axis direction).

According to some embodiments, FIG. 8 shows the plurality of lead units LU1 including a first lead unit LU1a, a second lead unit LU1b, and a third lead unit LU1c. According to some embodiments, the number of the plurality of lead units LU1 may be determined in various ways depending on the conditions of the display panel DP. According to some embodiments, the number of the plurality of lead units LU1 arranged on the circuit member 101 may be 1, 2, 3, 4, 5, or more.

The lead unit LU1 may be arranged at a position corresponding to the pad unit PU1, for example, to overlap the pad unit PU1 along the third direction (the Z-axis direction). The plurality of pad units PU1 and the plurality of lead units LU1 may match each other, for example, may be arranged in a one-to-one matching manner. According to some embodiments, the lead unit LU1 may be electrically connected to the pad unit PU1, for example, in contact with the pad unit PU1.

The lead unit LU1 may include a conductive material, for example, a material including copper (Cu) and tin (Sn), and the plurality of lead units LU1 may include the same material. The plurality of lead units LU1 may be formed through the same process.

The dummy pattern unit DU1 may be arranged spaced apart from the lead unit LU1. The dummy pattern unit DU1 may be arranged to overlap a space between the plurality of lead units LU1. For example, the dummy pattern unit DU1 may correspond to a space between two adjacent lead units LU1 in the third direction (the Z-axis direction), and may not overlap the lead units LU1.

The dummy pattern unit DU1 may be electrically insulated from the lead unit LU1 and the circuit member 101 including the lead unit LU1.

An intermediate insulating layer NCF1 may be arranged in a space between the substrate SUB1 and the circuit member 101. According to some embodiments, the intermediate insulating layer NCF1 may be arranged to be in contact with the pad unit PU1, the dummy pattern unit DU1, the lead unit LU1, and the adjacent insulating layer IL1.

The arrangement of the dummy pattern unit DU1 may cause a decrease in volume of a space where the intermediate insulating layer NCF1 may be arranged. The arrangement of the dummy pattern unit DU1 may result in relatively reducing the thickness of the intermediate insulating layer NCF1, thereby allowing a precise thickness control of the display device 100.

According to some embodiments, the intermediate insulating layer NCF1 may include a non-conductive adhesive film or a molded underfill.

Referring to FIG. 8, the adjacent insulating layer IL1 may be located between the substrate SUB1 and the intermediate insulating layer NCF1. For example, the substrate SUB1 and the intermediate insulating layer NCF1 may be spaced apart from or may not be in contact with each other by the adjacent insulating layer IL1.

According to some embodiments, the adjacent insulating layer IL1 may be arranged without a gap in a space between the pad unit PU1 and the dummy pattern unit DU1. The adjacent insulating layer IL1 may be arranged such that an upper surface thereof is convex upward.

According to some embodiments, the adjacent insulating layer IL1 may have an asymmetrical shape with respect to the third direction (the Z-axis direction). The upper surface of the adjacent insulating layer IL1 may be uneven.

The pad unit PU1, the dummy pattern unit DU1, and the adjacent insulating layer IL1 may have heights based on a thickness direction of the display device. The height of the pad unit PU1 may be equal to or greater than the height of the adjacent insulating layer IL1. According to some embodiments, the height of the pad unit PU1 may be greater than a height of an edge of the adjacent insulating layer IL1 adjacent to the pad unit PU1. According to some embodiments, an extension line in the first direction (the X-axis direction) from an edge of an upper surface of the adjacent insulating layer IL1 may be lower than the height of the adjacent pad unit PU1.

For example, the adjacent insulating layer IL1 may be arranged through a photolithography process. The photolithography process may include a photosensitive material application step, an exposure step, and a development step. The adjacent insulating layer IL1 may include a photosensitive material, for example, may include a photosensitive organic material or a photosensitive resin.

According to some embodiments, the adjacent insulating layer IL1 may be applied to an area on the first connection area CA1 in an application step, for example, an area including an upper surface of the pad unit PU1, an upper surface of the dummy pattern unit DU1, a space between the pad unit PU1 and the dummy pattern unit DU1, and surrounding areas of the pad unit PU1 and the dummy pattern unit DU1. According to some embodiments, the adjacent insulating layer IL1 may be applied to an area including the entire first connection area CA1. In the subsequent exposure and development steps, an area of the adjacent insulating layer IL1 which is applied to the upper surface of the pad unit PU1 and the upper surface of the dummy pattern unit DU1 may be removed.

In this case, in the exposure step, a portion of the upper surface of the adjacent insulating layer IL1, which is adjacent to the pad unit PU1 and the dummy pattern unit DU1, may be exposed to light. The portion of the upper surface of the adjacent insulating layer IL1 which is exposed to light may be partially removed. According to some embodiments, the height of the adjacent insulating layer IL1 may be relatively reduced.

The height reduction of the adjacent insulating layer IL1 may occur unevenly on the upper surface of the adjacent insulating layer IL1. For example, the height of the adjacent insulating layer IL1 may be further reduced in an area, which is closer to the adjacent pad unit PU1 and the dummy pattern unit DU1, on the upper surface of the adjacent insulating layer IL1. In some embodiments, on the upper surface of the adjacent insulating layer IL1, an area closer to the pad unit PU1 and the dummy pattern unit DU1 may be more removed, while an area relatively farther from the pad unit PU1 and the dummy pattern unit DU1 may be less removed or may not be removed at all. Accordingly, the height of the adjacent insulating layer IL1 may decrease as the adjacent insulating layer IL1 is close to the pad unit PU1 and the dummy pattern unit DU1, and thus the upper surface of the adjacent insulating layer IL1 may have an upwardly convex shape.

The adjacent insulating layer IL1 may have a width based on the first direction (the X-axis direction). As the width of the adjacent insulating layer IL1 decreases, an area of an upper portion of the adjacent insulating layer IL1 may be more removed. According to some embodiments, in the exposure step, the area of the upper portion of the adjacent insulating layer IL1 may be more removed as a gap between mask patterns decreases. According to some embodiments, as the width of the adjacent insulating layer IL1 decreases, a ratio of the removed area of the adjacent insulating layer IL1 may increase relative to the entire adjacent insulating layer IL1. Under the same conditions, for example, in case that the thickness of the applied adjacent insulating layer IL1 is equal, the height of the adjacent insulating layer IL1 may be more reduced as the width of the adjacent insulating layer IL1 decreases.

The width of the adjacent insulating layer IL1 may correspond to a gap between the adjacent pad unit PU1 and the dummy pattern unit DU1. Therefore, by adjusting the gap between the adjacent pad unit PU1 and the dummy pattern unit DU1, the width of the adjacent insulating layer IL1 may be adjusted and the height of the adjacent insulating layer IL1 may also be adjusted. For example, while maintaining a gap between two adjacent pad units PU1, at least one dummy pattern unit DU1 may be further arranged between the pad units PU1, thereby relatively decreasing the width of the adjacent insulating layer IL1. According to some embodiments, by increasing the width of each of the adjacent pad unit PU1 and the dummy pattern unit DU1, the width of the adjacent insulating layer IL1 arranged between the pad unit PU1 and the dummy pattern unit DU1 may decrease.

Therefore, in case that the gap between the adjacent pad unit PU1 and the dummy pattern unit DU1 decreases, the height of the adjacent insulating layer IL1 arranged between the adjacent pad unit PU1 and the dummy pattern unit DU1 may be further reduced.

Depending on the height control (e.g., the height reduction) of the adjacent insulating layer IL1, a size of an area where the adjacent insulating layer IL1 is connected to (or in contact with) the lead unit LU1 may be relatively reduced, or the adjacent insulating layer IL1 may not be connected to the lead unit LU1. According to some embodiments, interference of the adjacent insulating layer IL1 with the connection between the pad unit PU1 and the lead unit LU1 may be relatively reduced. Accordingly, pressure applied in a direction from the lead unit LU1 toward the pad unit PU1 or pressure applied in an opposite direction may be efficiently transmitted to the lead unit LU1 and the pad unit PU1, and electrical connection or contact characteristics between the lead unit LU1 and the pad unit PU1 may be relatively improved.

According to some embodiments, the adjacent insulating layer IL1 which is arranged in the space between the adjacent pad unit PU1 and the dummy pattern unit DU1 may be arranged spaced apart from the lead unit LU1. In this case, in the direction from the lead unit LU1 toward the pad unit PU1, pressure applied by the lead unit LU1 may not be transmitted to the adjacent insulating layer IL1. Accordingly, pressure may be effectively applied to the pad unit PU1, thereby relatively improving the reliability of the electrical connection between the lead unit LU1 and the pad unit PU1.

FIG. 9 is a schematic view of an example of a cross-section taken along the line IX-IX′ of FIGS. 1 to 3 and 7.

The plurality of convex patterns 144 may be arranged on the pad unit PU1. According to some embodiments, the plurality of convex patterns 144 may be arranged spaced apart from one another along the second direction (the Y-axis direction), and according to some embodiments, the plurality of convex patterns 144 may be arranged at equal or different gaps for each pad unit PU1. For example, FIG. 7 or FIG. 9 illustrates a pad unit PU1 including three or four convex patterns 144. According to some embodiments, the number of the plurality of convex patterns 144 may be determined in various ways depending on the conditions of the display panel DP. According to some embodiments, the number of convex patterns 144 arranged on the pad unit PU1 is not limited to the embodiments and may be 3, 4, 5, or more.

The convex pattern 144 may include various materials, for example, may include inorganic or organic materials. According to some embodiments, the plurality of convex patterns 144 may include the same material as at least one of a plurality of insulating layers arranged in the display area DA under the same process. The sizes of the formed convex patterns 144 may be the same as or different from each other.

The convex pattern 144 may be arranged to be surrounded by at least one connection conductive layer. According to some embodiments, the plurality of convex patterns 144 may be arranged on a first connection conductive layer 143, and a second connection conductive layer 145 may be arranged on the plurality of convex patterns 144. For example, the plurality of convex patterns 144 may be arranged between the first connection conductive layer 143 and the second connection conductive layer 145, and may cover at least one area of the first connection conductive layer 143. The first connection conductive layer 143 and the second connection conductive layer 145 may be electrically connected in an area where the convex pattern 144 is not arranged.

According to some embodiments, a base conductive layer 141, a pad unit insulating layer 142, the first connection conductive layer 143, and the second connection conductive layer 145 may be sequentially arranged on the substrate SUB1, and the plurality of convex patterns 144 may be arranged between the first connection conductive layer 143 and the second connection conductive layer 145. In this case, the pad unit insulating layer 142 may include an opening, and the opening may be a contact hole CNT. For example, the base conductive layer 141 may be electrically connected to the first connection conductive layer 143 and the second connection conductive layer 145 through the contact hole CNT. The number of conductive layers arranged on the pad unit is not limited to the disclosed embodiments, and may be 3, 4, 5, or more.

Referring to FIG. 9, the contact hole CNT may be a portion in which the opening is formed on the pad unit PU1 and may have a shape recessed in the third direction (the Z-axis direction). Portions where the plurality of convex patterns 144 are arranged on the pad unit PU1 may form convex portions CP where the second connection conductive layer 145 protrudes convexly in the third direction (the Z-axis direction).

For example, the portion where the convex pattern 144 is arranged may overlap the convex portion CP. The convex portion CP may come into contact with the lead unit LU1 and may be electrically connected to the lead unit LU1.

Gaps between the plurality of convex portions CP arranged in one pad unit PU1 may be different, and may be the same if necessary. The gaps between the plurality of convex portions CP arranged in two adjacent pad units PU1 may be different for each pad unit PU1. According to some embodiments, the gap between the plurality of convex portions CP of each of the pad units PU1, which are arranged relatively outward, among the plurality of pad units PU1, may be narrower than the gap between the plurality of convex portions CP of each of the pad units PU1, which are arranged relatively inward. According to some embodiments, the number of the plurality of convex portions CP of each of the pad units PU1, which are arranged relatively outward, among the plurality of pad units PU1, may be greater than the number of the plurality of convex portions CP of each of the pad units PU1, which are arranged relatively inward. According to some embodiments, the number of the plurality of convex portions CP arranged on each of the plurality of pad units PU1 may be the same.

The plurality of convex portions CP may have different widths in the first direction (the X-axis direction) and the second direction (the Y-axis direction) or different heights in the third direction (the Z-axis direction).

FIG. 10 is an enlarged view of aspects of an area A1 in FIG. 8;

Referring to the embodiments of FIG. 10, upper surface and side surfaces of the base conductive layer 141 arranged on the substrate SUB1 may be covered by the pad unit insulating layer 142.

According to some embodiments, the first connection conductive layer 143 and the second connection conductive layer 145 arranged on the pad unit insulating layer 142 may have the same width in the first direction (the X-axis direction), and according to some embodiments, may have different widths in the first direction.

The base conductive layer 141, the first connection conductive layer 143, and the second connection conductive layer 145 may include various conductive materials. For example, the base conductive layer 141, the first connection conductive layer 143, and the second connection conductive layer 145 may include a metal layer, and for example, may include a conductive material including molybdenum (Mo), aluminum (Al), copper (Cu), titanium (Ti), or the like.

According to some embodiments, the base conductive layer 141, the first connection conductive layer 143, and the second connection conductive layer 145 may include the same material. According to some embodiments, the base conductive layer 141, the first connection conductive layer 143, and the second connection conductive layer 145 may include the same material, under the same process, as at least one of electrodes used in the display area DA, for example, the gate electrode G, the drain electrode D, the source electrode S, or the connection electrode CML described above.

The adjacent insulating layer IL1 may not overlap an area of the second connection conductive layer 145.

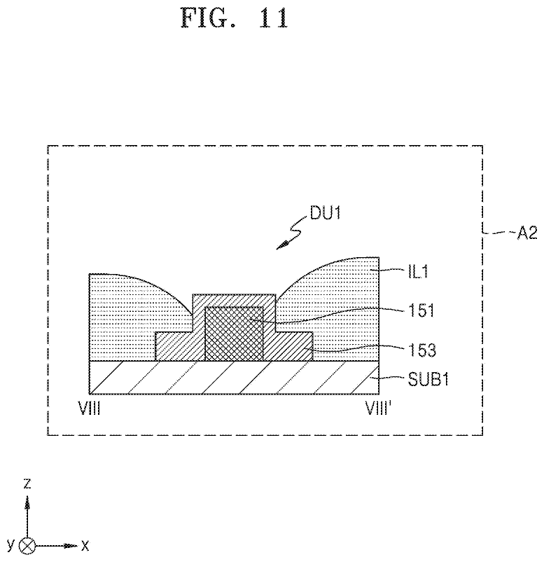

FIGS. 11 to 13 are enlarged views of an area A2 of FIG. 8, and views of modified examples.

Referring to FIG. 11, the dummy pattern unit DU1 may include an insulating material and may be arranged to have a height in the third direction (the Z-axis direction). Referring to FIG. 11, the dummy pattern unit DU1 may include a first dummy conductive layer 151 arranged on the substrate SUB1, and a dummy insulating layer 153 covering upper surface and side surfaces of the first dummy conductive layer 151. For example, the first dummy conductive layer 151 may be electrically insulated from and arranged not to be in contact with the adjacent insulating layer IL1 or the intermediate insulating layer NCF1, which may be in contact with the dummy insulating layer 153.

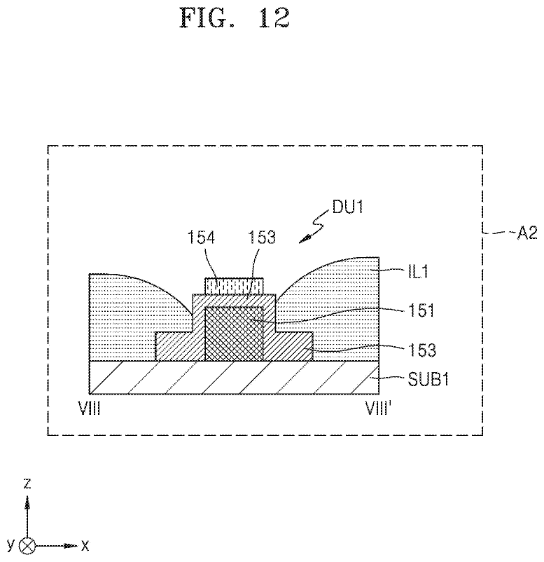

According to some embodiments, a conductive layer may be further arranged on the dummy insulating layer 153. For example, referring to FIG. 12, an upper conductive layer 154 may be arranged on the dummy insulating layer 153. The first dummy conductive layer 151 and the upper conductive layer 154 may be electrically insulated from each other, and, for example, may be arranged not to be in contact with each other by the dummy insulating layer 153.

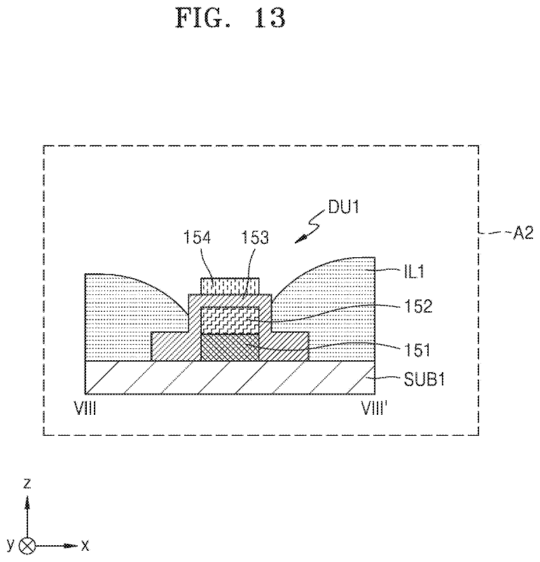

According to some embodiments, a dummy conductive layer may be arranged as a plurality of dummy conductive layers. Referring to FIG. 13, a second dummy conductive layer 152 may be arranged on the first dummy conductive layer 151, and the dummy insulating layer 153 may be arranged on the second dummy conductive layer 152. Accordingly, the dummy insulating layer 153 may cover an upper surface of the first dummy conductive layer 151 and the second dummy conductive layer 152 and side surfaces of the first dummy conductive layer 151 and the second dummy conductive layer 152. The first dummy conductive layer 151 and the second dummy conductive layer 152 may be electrically insulated from the upper conductive layer 154, and, for example, may be arranged not to be in contact with the upper conductive layer 154 by the dummy insulating layer 153.

According to some embodiments, the arranged dummy conductive layers may have the same width in the first direction (the X-axis direction). However, this is only an example, and at least three dummy conductive layers may be stacked in the third direction (the Z-axis direction).

Referring to FIGS. 11 to 13, the first dummy conductive layer 151, the second dummy conductive layer 152, and the upper conductive layer 154 may include various conductive materials. For example, the first dummy conductive layer 151, the second dummy conductive layer 152, and the upper conductive layer 154 may include a metal layer, and, for example, may include a conductive material including molybdenum (Mo), aluminum (Al), copper (Cu), titanium (Ti), or the like. According to some embodiments, the first dummy conductive layer 151, the second dummy conductive layer 152, and the upper conductive layer 154 may include the same material. According to some embodiments, the first dummy conductive layer 151, the second dummy conductive layer 152, and the upper conductive layer 154 may include the same material, under the same process, as at least one of the electrodes used in the display area DA, for example, the gate electrode G, the drain electrode D, the source electrode S, or the connection electrode CML, or the conductive layers used in the pad unit PU1, for example, the base conductive layer 141, the first connection conductive layer 143, and the second connection conductive layer 145.

The dummy pattern unit DU1 may be electrically insulated from the lead unit LU1 or the circuit member 101, and, for example, may be arranged spaced apart from the lead unit LU1 or the circuit member 101. According to some embodiments, the height of the dummy pattern unit DU1 in the third direction (Z-axis direction) may not be greater than the height of at least one of the two adjacent pad units PU1. For example, the height of the dummy pattern unit DU1 may not be greater than a height of at least one of areas of the pad unit PU1 where the convex patterns 144 are arranged.

The display device according to some embodiments may include the at least one dummy pattern unit DU1 between the plurality of pad units PU1. By virtue of the dummy pattern unit DU1, the width of the adjacent insulating layer IL1 arranged between the dummy pattern unit DU1 and the pad unit PU1 may be relatively reduced and the height of the adjacent insulating layer IL1 may be relatively reduced. For example, a degree of etching during a subsequent etching process may be controlled by increasing an area of the adjacent insulating layer IL1, which is exposed to light during a photolithography process, and the height of the adjacent insulating layer IL1 may be relatively reduced.

In this case, interference of the adjacent insulating layer IL1 with the connection between the pad unit PU1 and the lead unit LU1 may be relatively reduced, and pressure applied from the lead unit LU1 toward the pad unit PU1 or pressure applied in an opposite direction may be efficiently transmitted to the lead unit LU1 and the pad unit PU1. It may also be said that a decrease in connection reliability between the lead unit LU1 and the pad unit PU1 due to the adjacent insulating layer IL1 is suppressed. As a result, the electrical connection or contact characteristics between the pad unit PU1 and the circuit member 101 may be relatively improved, and the electrical characteristics and durability of the display device 100 may be enhanced.

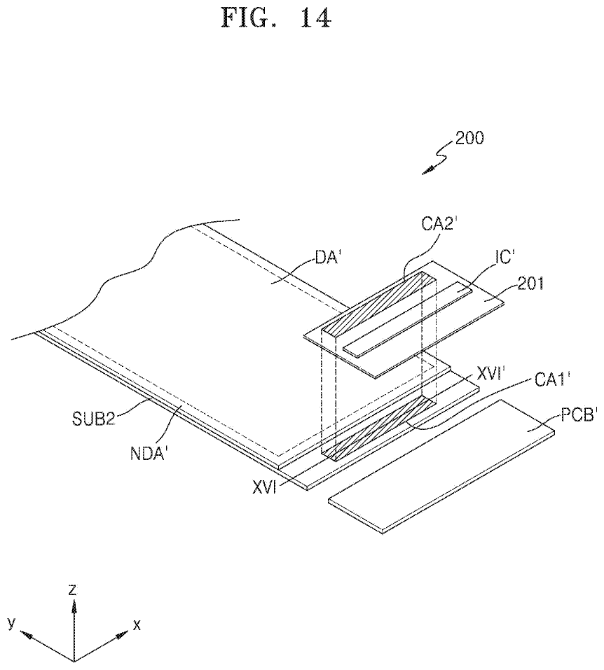

FIG. 14 is an exploded perspective view of a portion of a display device according to some embodiments.

Referring to FIG. 14, a display device 200 may include a substrate SUB2, a display area DA′ and a non-display area NDA′ on the substrate SUB2, a circuit member 201, and a printed circuit board PCB′. The display area DA′ may include an area where visible light is emitted on the substrate SUB2, and the non-display area NDA′ may surround the display area DA′. According to some embodiments, the non-display area NDA′ may be positioned outside an edge of the display area DA′ or outside a plurality of edges of the display area DA′.

The non-display area NDA′ may include a first connection area CA1′.

The circuit member 201 and the like may be arranged to be connected, for example, electrically connected to or in contact with a portion of the non-display area NDA′. For example, as shown in FIG. 14, a second connection area CA2′ arranged on the circuit member 201 and the first connection area CA1′ in the non-display area NDA′ arranged on the substrate SUB2 may be arranged to be connected to or in contact with each other along a third direction (e.g., a Z-axis direction of FIG. 14). Here, a first direction (e.g., an X-axis direction of FIG. 14) may be a width or length direction of the substrate SUB2, a second direction (e.g., a Y-axis direction of FIG. 14) may be a direction crossing (or orthogonal to) the first direction, and the third direction may be a direction crossing (or orthogonal to) the first direction and the second direction, for example, may correspond to a thickness direction of the substrate SUB2.

At least one circuit element, for example, a driver chip IC′ may be arranged on the circuit member 201. According to some embodiments, the at least one circuit element may be arranged in a chip on film (COF) manner on the circuit member 201. For example, the driver chip IC′ may be arranged on the circuit member 201, and the circuit member 201 may include a flexible printed circuit board (FPC).

The circuit member 201 may be electrically connected to a display panel DP′ and, for example, may transmit an electrical signal to the display panel DP′. According to some embodiments, the driver chip IC′ of the circuit member 201 may transmit an electrical signal to the display panel DP′.

According to some embodiments, the circuit member 201 may be electrically connected to the printed circuit board PCB′. In this case, the printed circuit board PCB′ may transmit an electrical signal to the circuit member 201. The printed circuit board PCB′ may include a flexible printed circuit board (FPC).

According to some embodiments, the structures of FIGS. 4 to 6 may be substantially identically applied to these embodiments or applied with some modifications within a similar range.

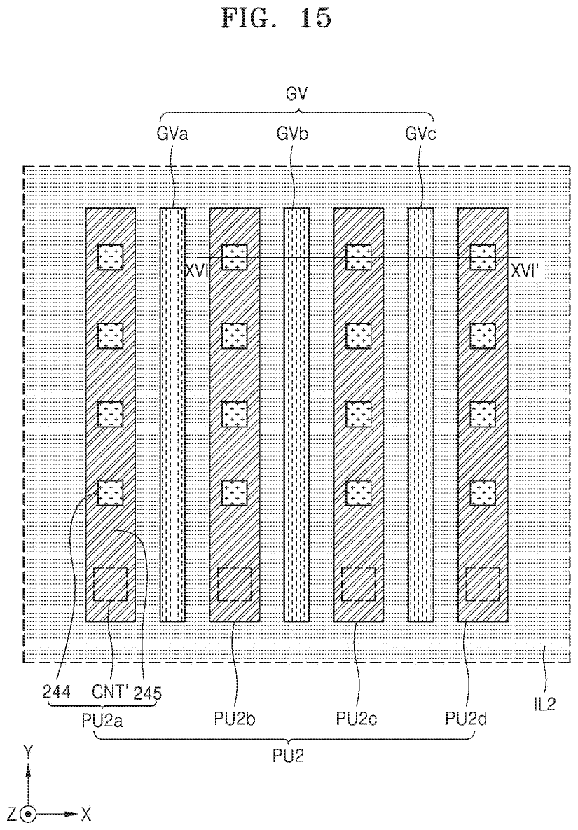

FIG. 15 is a partial enlarged view of the first connection area CA1′ in FIG. 14.

Referring to FIG. 15, a plurality of pad units PU2 may be arranged on the first connection area CA1′. For example, FIG. 15 shows a plurality of pad units PU2 including a first pad unit PU2a, a second pad unit PU2b, a third pad unit PU2c, and a fourth pad unit PU2d. According to some embodiments, the number of the plurality of pad units PU2 may be determined in various ways depending on the conditions of the display panel DP′. For example, the number of the plurality of pad units PU2 arranged on the first connection area CA1′ may be 1, 2, 3, 4, 5, or more.

Each of the plurality of pad units PU2 may have a width and a length. For example, each pad unit PU2 may have a length by extending in the second direction (the Y-axis direction) and a width with respect to the first direction (the X-axis direction).

The plurality of pad units PU2 may be arranged spaced apart from one another along the first direction (the X-axis direction). According to some embodiments, the plurality of pad units PU2 may be arranged in parallel to be spaced apart from one another along the first direction (the X-axis direction).

At least one convex pattern 244 and a conductive layer covering the convex pattern 144 may be arranged on each of the plurality of pad units PU2, and an opening may be arranged in an area of the corresponding pad unit PU2. According to some embodiments, the pad unit PU2 may include at least one convex pattern 244, a second connection conductive layer 245 covering the at least one convex pattern 244, and a contact hole CNT′ arranged in an area of the pad unit PU2. Similar to the structure shown in FIG. 7, the convex pattern 244 shown in FIG. 15 is covered by the second connection conductive layer 245, but for convenience of explanation, the convex pattern 244 of FIG. 15 is illustrated with a solid line.

An adjacent insulating layer IL2 may be arranged between two adjacent pad units PU2, and the adjacent insulating layer IL2 may include a groove GV. For example, at least one groove GV may be arranged to correspond to at least a space between two adjacent pad units PU2. For example, as shown in FIG. 15, one groove GVa may be arranged between the first pad unit PU2a and the second pad unit PU2b.

The groove GV may be arranged spaced apart from the two adjacent pad units PU2 along the first direction (the X-axis direction). According to some embodiments, a gap between a pad unit PU2 adjacent to the groove GV on one side and the groove GV may be equal to a gap between a pad unit PU2 adjacent to the groove GV on another side and the groove GV

According to some embodiments, the groove GV may be arranged in parallel to two adjacent pad units PU2 along the first direction. According to some embodiments, each of the plurality of pad units PU2 and each of the plurality of grooves GV may be alternately arranged to be spaced apart from each other along the first direction (the X-axis direction).

The adjacent insulating layer IL2 may be arranged in a space between the adjacent pad unit PU2 and the groove GV. According to some embodiments, the adjacent insulating layer IL2 may also be arranged around the pad unit PU2 and the groove GV, for example, may be arranged to surround the pad unit PU2 and the groove GV.

According to some embodiments, the adjacent insulating layer IL2 may be arranged to be in contact with the pad unit PU2 and the groove GV on the first connection area CA1′. According to some embodiments, the adjacent insulating layer IL2 may be arranged to cover the entire first connection area CA1′ excluding the pad unit PU2 and the groove GV.

The adjacent insulating layer IL2 may include an insulating material, for example, an insulating material including an organic material.

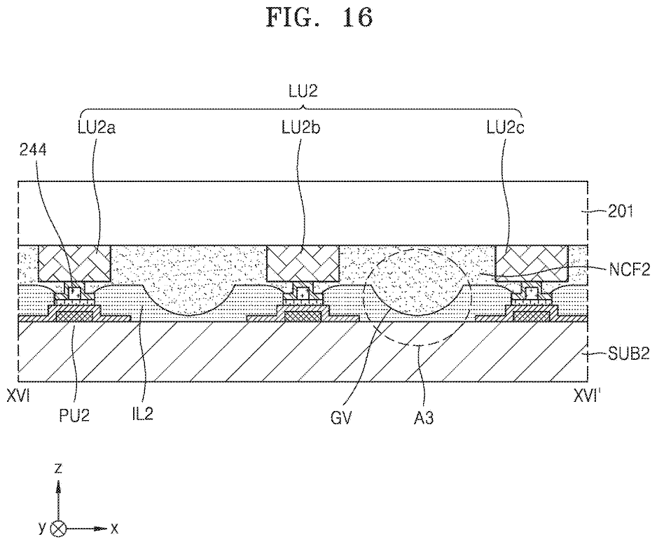

FIG. 16 is a schematic view of an example of a cross-section taken along the line XVI-XVI′ of FIGS. 14 and 15.

Referring to FIG. 16, the first connection area CA1′ on the substrate SUB2 and the second connection area CA2′ on the circuit member 201 may be connected to, for example, in contact with each other along the third direction (the Z-axis direction). Accordingly, the display panel DP′ and the circuit member 201 may be electrically connected.

The pad unit PU2 and the adjacent insulating layer IL2 may be arranged on the substrate SUB2, and the adjacent insulating layer IL2 may include the groove GV. An area of the pad unit PU2 may be electrically connected to the circuit member 201, for example, may be in contact with the circuit member 201.

A lead unit LU2 protruding in a direction toward the pad unit PU2 may be arranged on the circuit member 201. The lead unit LU2 may extend along the second direction (the Y-axis direction). The lead unit LU2 according to some embodiments may be arranged as a plurality of lead units, and the plurality of lead units LU2 may be arranged spaced apart along the first direction (the X-axis direction). For example, the plurality of lead units LU2 may be arranged in parallel along the first direction (the X-axis direction).

According to some embodiments, FIG. 16 shows the plurality of lead units LU2 including a first lead unit LU2a, a second lead unit LU2b, and a third lead unit LU2c. According to some embodiments, the number of the plurality of lead units LU2 may be determined in various ways depending on the conditions of the display panel DP′. According to some embodiments, the number of the plurality of lead units LU2 arranged on the circuit member 201 may be 1, 2, 3, 4, 5, or more.

The lead unit LU2 may be arranged at a position corresponding to the pad unit PU2, for example, to overlap the pad unit PU1 along the third direction (the Z-axis direction). The plurality of pad units PU2 and the plurality of lead units LU2 may match each other, for example, may be arranged in a one-to-one matching manner. According to some embodiments, the lead unit LU2 may be electrically connected to the pad unit PU2, for example, may be in contact with the pad unit PU2.

The lead unit LU2 may include a conductive material, for example, a material including copper (Cu) and tin (Sn), and the plurality of lead units LU2 may include the same material.

The groove GV may be arranged to overlap a space between the plurality of lead units LU2. For example, the groove GV may correspond to a space between two adjacent lead units LU2 with respect to the third direction (the Z-axis direction), and may not overlap the lead units LU2.

An intermediate insulating layer NCF2 may be arranged in a space between the substrate SUB2 and the circuit member 201. According to some embodiments, the intermediate insulating layer NCF2 may be arranged to be in contact with the pad unit PU2, the groove GV, the lead unit LU2, and the adjacent insulating layer IL2. According to some embodiments, the intermediate insulating layer NCF2 may include a non-conductive adhesive film or a molded underfill.

The pad unit PU2 and the adjacent insulating layer IL2 may have heights based on a thickness direction of the display device. The height of the pad unit PU2 may be equal to or greater than the height of the adjacent insulating layer IL2. According to some embodiments, the height of the pad unit PU2 may be greater than a height of an edge of the adjacent insulating layer IL2 adjacent to the pad unit PU2. According to some embodiments, an extension line in the first direction (the X-axis direction) from an edge of an upper surface of the adjacent insulating layer IL2 may be lower than the height of the adjacent pad unit PU2.

The adjacent insulating layer IL2 may be arranged using various processes, and for example, may be arranged through a process similar to the process of forming the adjacent insulating layer IL1 of the above-described embodiments, for example, through a photolithography process.

According to some embodiments, the adjacent insulating layer IL2 may be applied to an area on the first connection area CA1′, for example, an area covering the plurality of pad units PU2, in an application step. According to some embodiments, the adjacent insulating layer IL2 may be applied to an area including the entire first connection area CA1′. In subsequent exposure and development steps, an area of the adjacent insulating layer IL2 which is applied to the upper surface of the pad unit PU2 may be removed. At least one area of the adjacent insulating layer IL2 which is located between two adjacent pad units PU2 may be removed, and for example, the groove GV may be formed.

In this case, in the exposure step, a portion of the upper surface of the adjacent insulating layer IL2 which is adjacent to the pad unit PU2 and the groove GV, may be exposed to light. The portion of the upper surface of the adjacent insulating layer IL2 which is exposed to light may be partially removed. According to some embodiments, the height of the adjacent insulating layer IL2 may be relatively reduced.

The height reduction of the adjacent insulating layer IL2 may occur unevenly on the upper surface of the adjacent insulating layer IL2. For example, the height of the adjacent insulating layer IL2 may be further reduced in an area, which is closer to the adjacent pad unit PU2 and the groove GV, on the upper surface of the adjacent insulating layer IL2. According to some embodiments, an area, which is closer to the pad unit PU2 and the groove GV, on the upper surface of the adjacent insulating layer IL2 may be more removed. Accordingly, the height of the adjacent insulating layer IL2 may decrease as the adjacent insulating layer IL2 is close to the pad unit PU2 and the groove GV, and thus the upper surface of the adjacent insulating layer IL1 may have an upwardly convex shape.

The groove GV and the adjacent insulating layer IL2 may have widths based on the first direction (the X-axis direction). In the thickness direction of the display device 200, the groove GV may have a depth and the adjacent insulating layer IL2 may have a height.

According to some embodiments, an area of an upper portion of the adjacent insulating layer IL2 may be more removed in the exposure step as the width of the adjacent insulating layer IL2 decreases. According to some embodiments, in the exposure step, the area of the upper portion of the adjacent insulating layer IL2 may be more removed as a gap between mask patterns decreases.

As an example of a process, the width or depth of the groove GV may be proportional to the size of the removed area of the adjacent insulating layer IL2.

Depending on the height control (e.g., the height reduction) of the adjacent insulating layer IL2, a size of an area where the adjacent insulating layer IL2 is connected to (or in contact with) the lead unit LU2 may be relatively reduced, or the adjacent insulating layer IL2 may not be connected to the lead unit LU2. According to some embodiments, interference of the adjacent insulating layer IL2 with the connection between the pad unit PU2 and the lead unit LU2 may be relatively reduced. Accordingly, pressure applied in a direction from the lead unit LU2 toward the pad unit PU2 or pressure applied in an opposite direction may be efficiently transmitted to the lead unit LU2 and the pad unit PU2, and electrical connection or contact characteristics between the lead unit LU2 and the pad unit PU2 may be relatively improved.

According to some embodiments, the adjacent insulating layer IL2 which is arranged in the space between the adjacent pad unit PU2 and the groove GV may be arranged spaced apart from the lead unit LU2. In this case, in the direction from the lead unit LU2 toward the pad unit PU2, pressure applied by the lead unit LU2 may not be transmitted to the adjacent insulating layer IL2. Accordingly, pressure may be effectively applied to the pad unit PU2, thereby relatively improving the reliability of the electrical connection between the lead unit LU2 and the pad unit PU2.

According to some embodiments, the structures of FIGS. 9 and 10 may be substantially identically applied to these embodiments or applied with some modifications within a similar range.

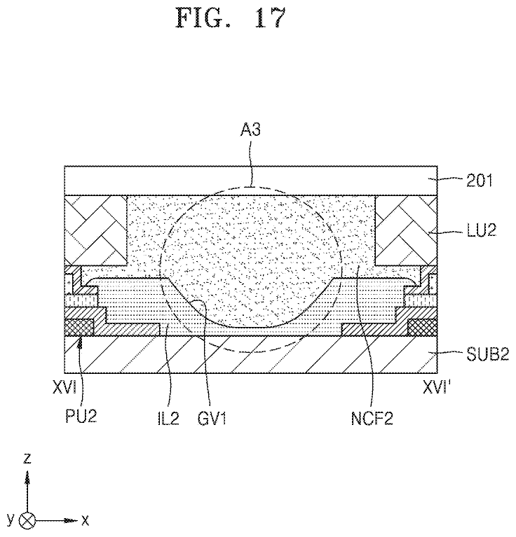

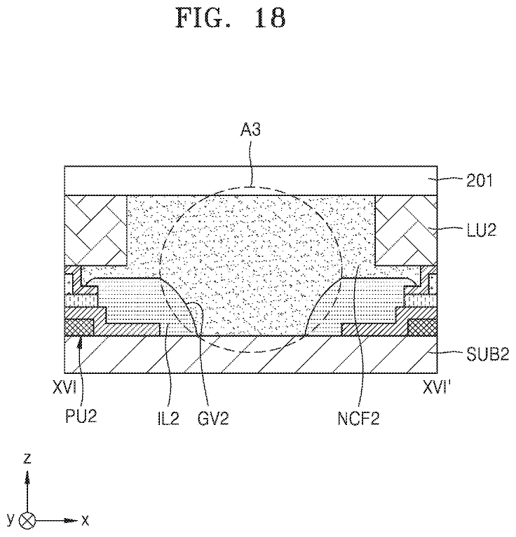

FIGS. 17 and 18 are enlarged views of aspects of an area A3 in FIG. 16. For example, FIG. 18 illustrates a modified example of FIG. 17.

A groove GV1 may be arranged in an area of the adjacent insulating layer IL2 located between two adjacent pad units PU2. For example, the groove GV1 may be formed by recessing the upper surface of the adjacent insulating layer IL2 located between two adjacent pad units PU2, or by removing a portion of an area, which is adjacent to the circuit member 201, of the adjacent insulating layer IL2 located between the two adjacent pad units PU2.

Referring to the embodiments of FIG. 17, the groove GV1 may be formed by recessing the upper surface of the adjacent insulating layer IL2 while forming a gentle curve toward the substrate SUB2, and may be formed, for example, by etching a portion of the adjacent insulating layer IL2. A bottom surface of the groove GV1 may be arranged to be spaced apart from an upper surface of the substrate SUB2. Therefore, the adjacent insulating layer IL2 arranged between two adjacent pad units PU2 may not be disconnected by the groove GV1. According to some embodiments, the groove GV1 may have an asymmetrical shape with respect to the Z-axis, and may be uneven.

Referring to the embodiments of FIG. 18, a groove GV2 may have a hole shape, and for example, may be formed by etching an area, corresponding to an entire thickness in a thickness direction, of the adjacent insulating layer IL2. According to some embodiments, the bottom of the groove GV2 may also correspond to the upper surface of the substrate SUB2. Accordingly, the adjacent insulating layer IL2 arranged between the two adjacent pad units PU2 may be disconnected by the groove GV2, and, according to some embodiments, an intermediate insulating layer NCF2 may be in contact with the substrate SUB2 through an opening.

Side surfaces of the groove GV2 may have a convex arcuate shape toward the adjacent pad units PU2 or may have a convex arcuate shape in an opposite direction. According to some embodiments, the groove GV2 may have an asymmetrical shape with respect to the Z-axis, and may be uneven.

According to some embodiments, the display device 200 may optionally include the groove GV1 of FIG. 17 or the groove GV2 of FIG. 18, and according to some embodiments, may include at least one groove GV1 of FIG. 17 and at least one groove GV2 of FIG. 18.

Referring to FIGS. 16 to 18, the groove GV1 or GV2 may have a width based on the first direction (the X-axis direction) and a depth based on the third direction (the Z-axis direction). The plurality of grooves GV1 or GV2 may have different widths and depths, or may have the same width or depth as required.

The display device according to some embodiments may include at least one groove GV between the plurality of pad units PU2. For example, the adjacent insulating layer IL2 may be arranged between two adjacent pad units PU2, and may include the groove GV. Through the groove GV, interference of the adjacent insulating layer IL2 with the connection between the pad unit PU2 and the lead unit LU2 may be relatively reduced, and pressure applied from the lead unit LU2 toward the pad unit PU2 or pressure applied in an opposite direction may be efficiently transmitted to the lead unit LU2 and the pad unit PU2. It may also be said that a decrease in connection reliability between the lead unit LU2 and the pad unit PU2 due to the adjacent insulating layer IL2 is relatively reduced or suppressed. As a result, the electrical connection or contact characteristics between the pad unit PU2 and the circuit member 201 may be relatively improved, and the electrical characteristics and durability of the display device 200 may be enhanced.

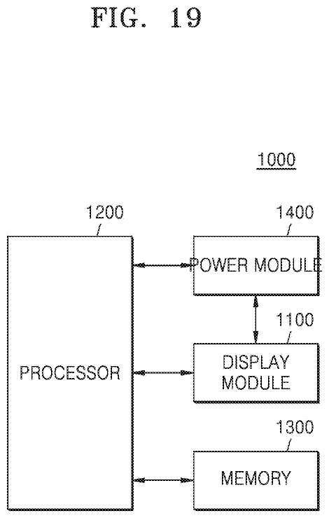

FIG. 19 is a view for explaining an electronic device to which a display device according to some embodiments is applied.

The display device according to some embodiments included in this specification may be applied to various electronic devices. According to some embodiments, the electronic device may include at least one of the display devices according to the embodiments included in the specification, and optionally may further include modules or devices having additional functions in addition to the display devices.

Referring to FIG. 19, an electronic device 1000 according to some embodiments may include a display module 1100, a processor 1200, a memory 1300, and a power module 1400.

The processor 1200 may include at least one of a central processing unit (CPU), an application processor (AP), a graphic processing unit (GPU), a communication processor CP, an image signal processor (ISP), or a controller. For example, the processor 1200 may operate by executing at least one program.

The memory 1300 may store data information which is necessary for the operation of the processor 1200 or the display module 1100. In case that the processor 1200 executes an application stored in the memory 1300, an image data signal and/or an input control signal may be transmitted to the display module 1100, and the display module 1100 may process the received signal and output image information through a display screen.

The power module 1400 may include a power supply module, such as a power adapter or a battery device, and a power conversion module which converts power supplied by the power supply module to generate power required for the operation of the electronic device 1000.

At least one of the components of the electronic device 1000 may be included in the display device according to the foregoing embodiments. Some of individual modules functionally included in a single module may be included in the display device and others may be provided separately from the display device. For example, the display device may include the display module 1100, and the processor 1200, the memory 1300, and the power module 1400 may be provided as other devices inside the electronic device 1000 other than the display device.

According to some embodiments, the electronic device 1000 may be configured such that the display device according to the embodiments of the specification described above is included in the display module 1100.

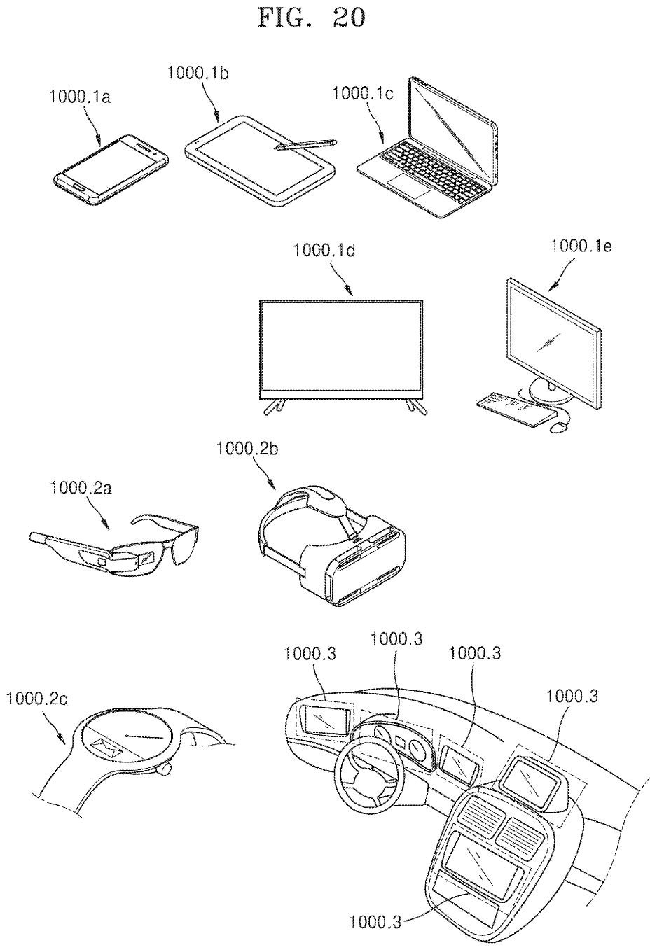

FIG. 20 is a view for explaining various examples of the electronic device of FIG. 19.

Referring to FIG. 20, various electronic devices to which the display device according to the embodiments is applied may include image display electronic devices, such as a smart phone 1000.1a, a tablet PC 1000.1b, a laptop 1000.1c, a TV 1000.1d, and a desk monitor 1000.1e, wearable electronic devices including display devices, such as smart glasses 1000.2e, a head mounted display 1000.2b, and a smart watch 1000.2c, and vehicle electronic devices 1000.3 including display devices, such as a center information display (CID) arranged on a dashboard, center fascia, and dashboard of an automobile, and a room mirror display.

A display device and an electronic device according to some embodiments may achieve relatively improved electrical reliability.

Each of the embodiments described above may be implemented independently, but it is obvious that the structure of each of the embodiments may be applied in combination to other embodiments.

The disclosure has been described with reference to the embodiments illustrated in the drawings, but this is only an example. It will be understood by those of ordinary skill in the art that various modifications and equivalents may be made thereto. Therefore, the true technical protection scope of the disclosure should be defined by the technical idea of the appended claims.

The specific executions described in the embodiments are merely illustrative, and do not limit the scope of the disclosure in any way. Furthermore, unless otherwise indicated obviously by terms, such as “essential”, “important”, and the like, a component may not be a necessary component for the application of the disclosure.

In the specification (particularly, in the claims) of the embodiments, the use of the term “the” and similar referential terms may refer to both the singular and the plural.

In case that a range is described in the embodiments, it includes the invention to which individual values within the range are applied (unless otherwise indicated herein). This is the same as stating each individual value constituting the above range in the detailed description.

Finally, the steps of the method according to some embodiments may be performed in any suitable order unless otherwise explicitly indicated herein or otherwise clearly contradicted by context. The embodiments are not necessarily limited by the order of steps described above.

The use of any examples or illustrative terms in the disclosed embodiments is merely to describe aspects of some embodiments in more detail, and unless limited by the claims, the scope of the embodiments are not limited by the examples or illustrative terms.

Further, it will be understood by those skilled in the art that various modifications, combinations and changes may be made depending on design conditions and factors within the scope of the appended claims or their equivalents.

What is claimed is:

1. A display device having a display area and a non-display area, the display device comprising:
a plurality of pad units in the non-display area;
at least one dummy pattern unit between adjacent pad units among the plurality of pad units; and
an adjacent insulating layer at least between the pad units and the dummy pattern unit, and arranged not to cover at least one area among areas of the plurality of pad units.

2. The display device of claim 1, further comprising
a circuit member electrically connected to the plurality of pad units,
wherein the circuit member comprises
a plurality of lead units electrically connected to the at least one area, not covered by the adjacent insulating layer, among the areas of the plurality of pad units, and spaced apart from the dummy pattern unit.

3. The display device of claim 2, wherein
the dummy pattern unit overlaps a space between adjacent lead units among the plurality of lead units.

4. The display device of claim 2, further comprising
an intermediate insulating layer between the plurality of pad units and the circuit member.

5. The display device of claim 2, wherein
each of the plurality of lead units of the circuit member and an area of the corresponding pad unit are in contact with each other.

6. The display device of claim 5, wherein
each of the plurality of pad units comprises at least one convex portion protruding toward the circuit member, and
an area of the at least one convex portion is in contact with the corresponding lead unit.

7. The display device of claim 6, wherein
the pad unit comprises:
a base conductive layer;
at least one connection conductive layer electrically connected to the base conductive layer; and
a convex pattern corresponding to the at least one convex portion and arranged between the base conductive layer and the at least one connection conductive layer.

8. The display device of claim 7, wherein
the convex pattern comprises an organic material.

9. The display device of claim 1, wherein
the dummy pattern unit comprises:
at least one dummy conductive layer; and
a dummy insulating layer covering the at least one dummy conductive layer.

10. The display device of claim 1, wherein
the dummy pattern unit and the plurality of pad units have heights based on a thickness direction of the display device, and
the height of the dummy pattern unit
is not greater than the height of each of the plurality of pad units.

11. The display device of claim 1, wherein
based on a thickness direction of the display device,
the adjacent insulating layer and the plurality of pad units have heights, and
the height of the adjacent insulating layer is not greater than the height of each of the plurality of pad units.

12. A display device having a display area and a non-display area, the display device comprising:
a plurality of pad units in the non-display area;
an adjacent insulating layer between adjacent pad units among the plurality of pad units; and
at least one groove in the adjacent insulating layer and spaced apart from the plurality of pad units.

13. The display device of claim 12, further comprising
a circuit member electrically connected to the plurality of pad units,
wherein the circuit member comprises
a plurality of lead units electrically connected to the plurality of pad parts and spaced apart from the at least one groove.

14. The display device of claim 13, wherein
the at least one groove overlaps a space between adjacent lead units among the plurality of lead units.

15. The display device of claim 13, further comprising
an intermediate insulating layer between the plurality of pad units and the circuit member.

16. The display device of claim 13, wherein
each of the plurality of lead units of the circuit member and an area of the corresponding pad unit are arranged to be in contact with each other.

17. The display device of claim 16, wherein
each of the plurality of pad units comprises at least one convex portion protruding toward the circuit member, and
an area of the at least one convex portion is in contact with the corresponding lead unit.

18. The display device of claim 17, wherein
the pad unit comprises a convex pattern comprising an organic material to correspond to the at least one convex portion.

19. The display device of claim 12, wherein
based on a thickness direction of the display device,
the adjacent insulating layer and the plurality of pad units have heights, and
the height of the adjacent insulating layer is not greater than the height of each of the plurality of pad units.

20. An electronic device comprising a display device in which a processor is configured to execute at least one application and to realize at least one image,
wherein the display device has a display area and a non-display area,
the display device comprises:
a plurality of pad units in the non-display area;
at least one dummy pattern unit between adjacent pad units among the plurality of pad units; and
an adjacent insulating layer arranged at least between the pad units and the dummy pattern unit, and arranged not to cover at least one area among areas of the plurality of pad units.
